(19) United States
(12) Patent Application Publication
(10) Pub. No.: US 2017/0146608 A1
(43) Pub. Date: May 25, 2017

(54) METHOD OF DYNAMICALLY EXTRACTING ENTROPY OF BATTERY

(71) Applicant: Korea Advanced Institute of Science and Technology, Daejeon (KR)

(72) Inventors: SANG-GUG LEE, Daejeon (KR); Guillaume Thenaisie, Daejeon (KR)

(21) Appl. No.: 15/044,400

(22) Filed: Feb. 16, 2016

(30) Foreign Application Priority Data
Nov. 20, 2015 (KR) 10-2015-0163255

(51) Int. Cl. G01R 31/36

(52) U.S. Cl. CPC G01R 31/3651; G01R 31/3675; G01R 31/3679; G01R 31/361

(57) ABSTRACT

Disclosed is a method of dynamically extracting entropy of battery. At every measurement of a SOC of a battery estimated in a BMS, a temperature of the battery is measured and an OCV of the battery is estimated and then stored. Entropy of the current state of the battery can be obtained through calculation using the temperature value and the OCV value newly stored. SOH and SOC of the battery are updated based on the entropy value newly calculated. The conventional BMS estimates SOH through internal resistance of the battery without using the entropy, but the method allows thermodynamically and analytically understanding the internal state of the battery by using the entropy, and conceiving precisely the battery state by monitoring SOH as well as SOS.

### CROSS-REFERENCE TO RELATED APPLICATION

This application claims priority under 35 USC §119 to Korean Patent Application No. 10-2015-0163255, filed on Nov. 20, 2015 in the Korean Intellectual Property Office (KIPO), the contents of which are herein incorporated by reference in their entirety.

### BACKGROUND

1. Technical Field

The present invention relates to a battery, and more particularly to a method for measuring entropy of the battery dynamically.

2. Description of the Related Art

Today, around 1.3 billion people have no access to electricity and this number is currently projected to barely change in the foreseeable future. It is forecasted that some 1.2 billion people globally will be still situated in an environment without access to electricity in 2030. The problem is particularly acute in rapidly developing areas of Asia and Africa, where the combination of population growth and industrial development is placing huge demands on the existing electrical infrastructure. However, in the countries where the distribution grid infrastructure itself is lacking, another market for domestic and consumer applications which are not connected to mains electricity is growing rapidly. Devices from the market are frequently powered by batteries, kerosene or diesel generators. However, as the fossil energy will disappear in the near future and new actors such as China or India are absorbing all the oil and gas production increase, it is predicted that the need for batteries will grow significantly over the next decades.

There are also an increasing demand for off-grid applications in the developed countries. The people in the countries are using more and more portable electronics such as laptop computers, smartphones, and the like. Markets of electrical vehicles (EV) or hybrid electric vehicles (HEV) start to stretch themselves as the people embrace them due to concerns about environment and economy. In these countries, the internet of things (IoT) is also rapidly increasing, in addition to the already growing demand for energy storage solutions.

The main solution to store electricity in all these devices is the battery even if sometimes small systems rely on hyper-capacitors as well. The majority of currently used batteries are lithium-based batteries such as Li-Ion, Life-Po, etc. due to their higher power densities and fast charging abilities. Also, the lithium-based batteries have low self-discharge, and don't have any requirements for priming. Thus, nowadays the lithium-based batteries are used to power a wide variety of consumer goods ranging from the mobile phones to children toys, e-bikes and passenger vehicles. The lithium-based batteries are already the majority of the battery market, and demands for them are still increasing continuously, with an expectation of their markets to grow 4 times by 2020.

Recently, a hyper capacitor is emerging as a new way to store energy. The hyper capacity provides a high energy density and thus can store almost as much electricity as the battery at a given weight, also having a long life. Compared with the battery, the hyper capacitor is much faster and easier to charge, being safer in use, showing much lower resistance, and providing an excellent low-temperature charge and discharge performance. However, the hyper capacitor has high self-discharge, low cell energy and a linear discharge voltage, which prevent it from using the full energy spectrum. Due to these disadvantages, the hyper capacitor fails to take a main position in the market.

Therefore the lithium-based batteries still dominate the market and such a situation will continue for a long time. However, the lithium-based batteries also face some challenges. They are not as robust as some other rechargeable technologies. They require protection from being over charged and discharged too far. Also, they are sensitive to temperature and misuses of voltage and current. If proper conditions are not satisfied, their life will degrade easily.

Besides, aging process occurring in the lithium-based batteries is another problem. It is dependent upon not only time or calendar but also the number of charge/discharge cycle that the batteries have undergone. What is more, they are potentially explosive and can set fire if not under proper protection.

To solve these issues, battery management engineers have paid great efforts. They come up with battery models and empirical studies have been conducted to try to secure and increase the reliability of lithium use. From these models and studies, engineers have been developing algorithms and hardware to handle the battery security, user safety and battery operational condition. The battery management system (BMS) and lots of literatures produced from the studies define them in details, with various sets of functions.

Over the years, BMS performances have increased significantly, bringing the lithium-based battery technology to the masses. And still, BMS based new models from new empirical studies are being developed.

### SUMMARY

The main point in the development of the BMS is that it is performed by electrical and computer science engineers, who base their approach on empirical analysis and electrical modeling of the behavior of the batteries. The circuit shown in FIG. 3 represents an electrical modeling of a lithium-ion battery. Such methods provide the advantage of quick development, easy to embed solution and linear industrial development process (Chemists create battery, while electrical engineers and computer science engineers develop hardware, and algorithms and controls, respectively).

However, these electrical and computer science engineers usually have poor understanding about chemistry and thus cannot predict battery behaviors out of experienced situations. Such a situation may lead to hazardous situations and accidents. It is important to note that these accidents may occur at any level of the market, from high-end products (Boeing, Tesla, etc.) to more modest products (e-cigarette). Therefore there is a vital need for a more fundamental approach, relying on a deep and good understanding of the chemistry and physical structure of the inner battery.

There has ever been proposed a method of measuring the entropy of a battery in a state of being unplugged while varying its temperature. However, since the method measures the entropy while maintaining the batter in a static state, it is disadvantageous as taking dozens of hours for the entropy measurement, which leads unsuitability for commercial use.

Thus, there is a real need from the BMS technologies for a dynamic thermodynamic parameter extraction method. The present invention has been made under the recognition of the above-mentioned problems of the conventional art to overcome its limitations. It is an object of the present invention to provide a method to extract the entropy values of a battery in real-time during the battery's charge and discharge.

It is another object of the present invention to provide a method to determine the entropy and enthalpy of the battery without unplugging the battery neither changing its temperature.

Furthermore, it is still another object of the present invention to provide a method to know an inner state of the battery thermodynamically and analytically using the entropy, and in particular to aware much more correctly the battery state through monitoring the state of health (SOH) as well as the state of safety (SOS) of the battery.

According to an embodiment of the present invention for achieving the object as above, a remaining capacity (SOC) of a battery is estimated with a BMS. Then, the estimated SOC value is compared for equality with a measurement reference value. If not equal, the SOC estimation is performed again. When the estimated SOC value is equal to the measurement reference value, during at least one cycle temperature of the battery is measured and an open circuit voltage (OCV) of the battery is estimated for each cycle, respectively. The data of temperature measurement and OCV estimation are stored. Based on the newly stored data of the temperature measurement and the OCV estimation calculated is entropy of a current state of the battery. Based on the newly obtained entropy value, a state of health (SOH) value and a state of safety (SOS) value of the battery are update.

The conventional BMS estimates SOH through the battery internal resistance without use of entropy, but the present invention can thermodynamically and analytically grasp the internal state of the battery by using entropy. Therefore, SOH as well as SOS can be monitored, thereby being able to know a more accurate battery status.

According to one embodiment of the present invention for achieving the object, there is provided a method of estimating dynamically the battery entropy. The dynamic estimation method of battery entropy, being a method to be performed by executing a program in a BMS connected to a battery, may include a step of measuring temperature of the battery of which functional status is situated in a dynamically varying state and estimating an OCV of the battery around a temperature measurement time, and a step of estimating an entropy change amount of the battery based on the temperature measurement value and the OCV estimation value.

According to one embodiment, the dynamic estimation method of the battery entropy may further include a step of estimating SOC of the battery while continuously monitoring the SOC and comparing an SOC estimation value with a preset measurement reference value to determine whether the SOC estimation value is equal to the preset measurement reference value. Through this step, when the monitored SOC value is equal to the present measurement reference value, the OCV estimation step and the entropy change estimation step may be carried out.

According to an embodiment of the dynamic estimation method of the battery entropy, the SOC estimation value may be calculated by linear regression analysis of a residual charge amount of the battery based on a predetermined battery temperature and the OCV of the battery.

According to another embodiment of the dynamic estimation of the entropy battery, the SOC estimation value may be calculated by the coulomb counting method for the measuring the current of the battery and integrated with respect to time them.

According to a further embodiment of the dynamic estimation of the entropy battery, the SOC estimation value may be calculated using the Kalman filtering.

According to one embodiment, the measurement reference value as a reference for estimating the entropy change amount may be set optionally depending on the need.

According to one embodiment, the dynamic estimation of the battery entropy, based on the entropy variation, the battery health state (State of Health: SOH) and/or safety conditions indicate a risk of the battery (State of Safety: SOS) a step of calculating the value may be further included.

According to one embodiment, the measure of the entropy variation, the SOC and the battery temperature, and the OCV can be measured by the measurement on the basis of the correlation between the OCV and the battery temperature is obtained by performing over a period of at least 2 cycles.

According to one embodiment, the amount of change of the entropy is measured, it can be performed over the whole period of the SOC.

According to one embodiment, the measured amount of change of the entropy is, the SOC has to be performed repeatedly each time change as the measurement reference value.

According to one embodiment, the OCV is independent of the measurement, it can be calculated by using the estimated SOC estimated value and the battery temperature.

According to one embodiment, the dynamic estimation of the battery entropy method, the estimated value of the OCV with the temperature measurement value may further comprise the step of storing in a database in the BMS.

According to one embodiment, the method of estimating the dynamic battery entropy can be implemented in integrated circuit systems.

According to one embodiment, the method of estimating the dynamic battery entropy can be implemented as a program running on a general purpose CPU or MCU.

According to one embodiment, the method of estimating the dynamic battery entropy may be implemented as a logic circuit.

According to one embodiment, the method of estimating the dynamic battery entropy may be implemented as a program running on the cloud system.

There have been lots of errors in expecting the battery state using the prior arts, which has resulted in frequent occurrence of several accidents such as battery explosion, reduced its life span, swelling of the battery, etc.

However, according to the present invention, it is possible to measure the dynamic change in entropy of the battery while the battery is used, thereby being able to accurately predict a condition of the battery as compared to the prior arts. Accordingly, it is possible to prevent accidents such as battery explosion in advance.

In addition, the present invention can dynamically estimate the entropy of the battery while charging or discharging the battery. The entropy estimation may also be made very quickly. This advantage extremely raises practicality of the present invention.

### BRIEF DESCRIPTION OF THE DRAWINGS

Illustrative, non-limiting example embodiments will be more clearly understood from the following detailed description taken in conjunction with the accompanying drawings.

FIG. 1 is a circuit diagram by electrically modeling a lithium-ion battery in accordance with conventional methods for ion battery;

FIG. 2 is a graph illustrating a schedule for measuring SOC of a battery by a static method in the process of charging the battery;

FIG. 3 is a flow chart illustrating a method for dynamically estimating the entropy of the battery according to the present invention;

FIG. 4 illustrates an example of the BMS for carrying out the method proposed by the present invention;

FIG. 5 illustrates another example of the BMS for carrying out the method proposed by the present invention;

FIG. 6 illustrates further another example of the BMS for carrying out the method proposed by the present invention for the application to a remote cloud computing system;

FIG. 7 illustrates an example of a characteristic curve, provided in any data sheet of the Li-ion battery cell, showing the relationship between a battery capacity and an OCV of the battery;

FIG. 8 is a graph showing illustratively the battery voltages for different discharge current values as a function of the battery SOC;

FIG. 9 illustrates an equivalent circuit diagram of the battery modeled in a form consisting of a voltage generator for generating an electromotive force and an internal resistance;

FIG. 10 is an exemplary graph illustrating entropy change as a function of the SOC;

FIG. 11 is an exemplary graph illustrating the relationship between the change in entropy and the battery degradation; and

FIG. 12 is an exemplary graph illustrating the relationship between the self-heating rate and the change in entropy.

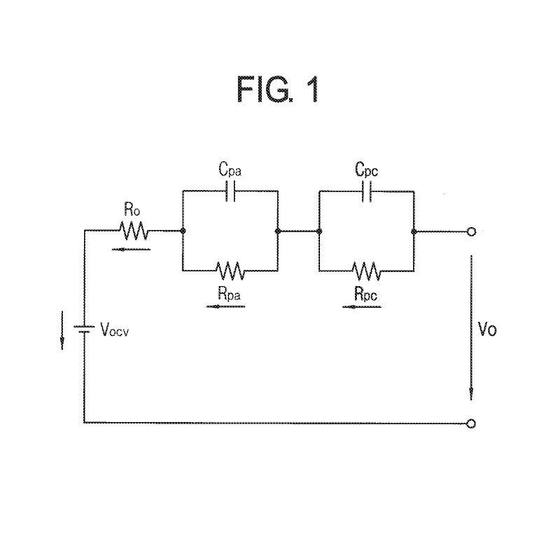

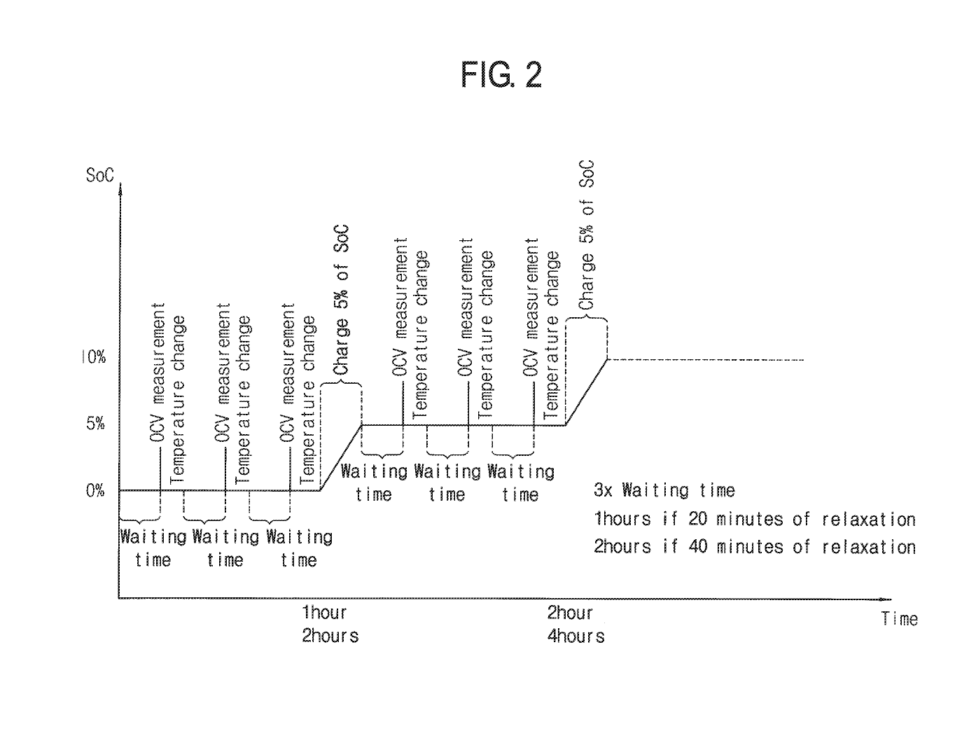

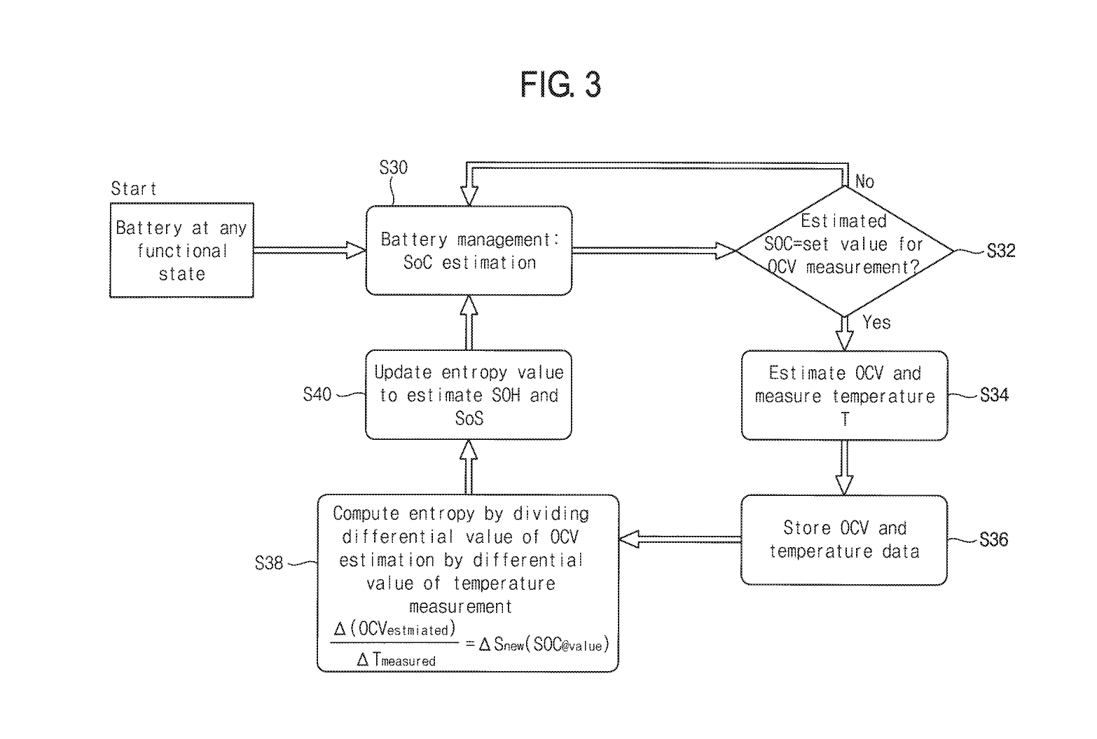

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this disclosure will be thorough and complete, and will fully convey the scope of the present inventive concept to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, detailed descriptions of the present invention will be given so as to easily carry out it with reference to the accompanying drawings.

### (1) DEFINITION OF TERMS

First, prior to describing the present invention in detail, a brief description of the meaning of key terms used in the present invention will be given.

Open circuit voltage (OCV): Voltage between an anode and a cathode of a battery cell when no load is connected to the battery cell, that is, no current flows out from the battery cell. Theoretically, the maximum value of the OCV becomes equal to the value of the electromotive force of the battery cell.

(Electric) Cell: A device for storing chemical energy that can be converted into electrical energy, usually in the form of direct current.

Battery: A device containing one or a group of cells to store the electrical energy.

State of Charge (SOC): This represents a charged level of the battery, and is equivalent of a fuel gauge for the battery. The units of SOC are percentage points (0%=empty; 100%=full). SOC is normally used when discussing the current state of a battery in use.

State of health (SOH): SOH is a figure of merit of the condition of a battery (or a cell, or a battery pack), compared to its ideal conditions. The units of SOH are percent points (100%=the battery's conditions match the battery's specifications). Typically, a battery's SOH will be 100% at the time of manufacture and will decrease over time and use. However, a battery's performance at the time of manufacture may not meet its specifications, in which case its initial SOH will be less than 100%.

State of Safety (SoS): A probability for a battery at given SOC and SOS to behave hazardously, that is, sudden combustion or explosion mostly.

Battery Management System (BMS): Any electronic system that manages a rechargeable battery (cell or battery pack), such as but not limited to, protecting the battery from operating outside its safe operating area, monitoring its state, calculating secondary data, reporting that data, controlling its environment, authenticating it and/or balancing it.

Enthalpy: A thermodynamic quantity equivalent to the total heat content of a system. It is equal to the internal energy of the system plus the product of pressure and volume. The change in enthalpy of a system is associated with a particular chemical process.

Entropy: A thermodynamic quantity representing the unavailability of a system's thermal energy for conversion into a mechanical work, often interpreted as the degree of disorder or randomness in the system.

Battery cycle: A part of the battery life composed of a discharge and a charge.

Li-based battery: All batteries whose chemistry relies on lithium as one of the two RedOx couples are considered as the lithium-based battery. It envisioned, but is not limited to, Li-Ion, Li—Po, Li—Mn, Li—Al, etc.

### (2) ELECTROCHEMICAL AND THERMODYNAMIC BASED STATIC MEASUREMENT METHOD FOR THE INTERNAL STATE OF A BATTERY

By relying on electrochemical thermodynamics measurements (ETMs), it is possible to determine in a non-destructive way the interstate of the Li-Ion battery, and the anode and cathode materials of the battery can be analyzed by computing the parameters such as SOC, SOH, and SOS of a battery. The way to do so is to monitor evolution of battery's OCV (E₀) along with the battery cell's temperature (T), at different values of the SOC. The OCV corresponds to lithium stoichiometry x at the anode and the cathode of the battery in LiₓC₆ and Li₁₋ₓCoO₂, respectively. The entropy ΔS(x) and enthalpy ΔH(x) state functions can be computed from the general thermodynamics laws:

$$\begin{matrix}Δ G ( x ) = - nF \frac{\partial {E}_{0} ( x )}{\partial T} & ( 1 ) \\ Δ G = Δ H - T Δ S & ( 2 ) \\ Δ H ( x ) = - F ( {E}_{0} + T \frac{\partial {E}_{0} ( x )}{\partial T} ) & ( 3 )\end{matrix}$$

In the above equations, G represents the Gibb's free energy, n denotes the amount of electron exchange in the conventional basic reaction, and F is the Faraday constant.

Since the entropy ΔS(x) and the enthalpy ΔH(r) in Equations (1) and (3) are measured at a defined state of charge of the battery, ‘x’, the entropy ΔS(x) and the enthalpy ΔH(x) can be defined as the local slope of the battery system' total entropy and the total enthalpy variation vs. ‘x’, respectively. Accordingly, there is no need for a reference state to determine the entropy ΔS(x) and the enthalpy ΔH(x).

From the equation (1), the entropy is then determined as the constant coefficient linking the temperature difference and the OCV difference between two measurement points. In other words, the entropy displays a fixed value for a given SOC, and the relationship between the OCV and the temperature is linear. (For the details, refer to equation (5) below along with descriptions of it)

As a way to measure entropy ΔS(x) and enthalpy ΔH(x), let's consider a method repeating a process consisting of ‘measuring the battery temperature and calculating the SOC and OCV of the battery at the measured temperature (‘a first step’)->waiting until the internal battery reaches a chemical relaxation state after the battery has been charged by a set value of the SOC, for example, 5% of SOC (‘a second step’) and then performing the first step’ until the battery is fully charged.

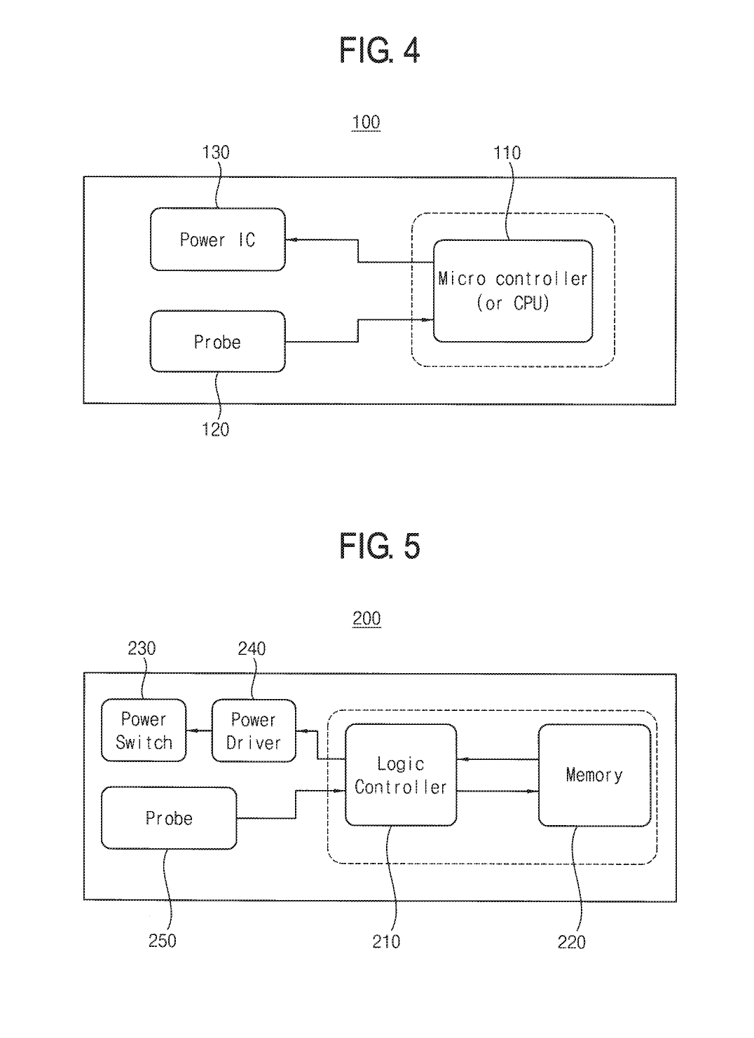

By the way, this method is a kind of static measurement method in that as can be know from the measurement schedule illustrated in FIG. 4, the battery charging must be stopped until the battery can transit from a charging state to the chemical relaxation state at every measurement interval of SOC, that is, during a time interval between an OCV measurement at a specific value of SOC and a next OCV measurement at a next specific value of SOC (the measurement of OCV may be performed, for example, at every 5% of SOC). That is, there is a consequent delay between two consecutive measurements of OCV, as the battery must relax from the charge, then it must reach the thermo-chemical equilibrium before the OCV is measured again. In a raw approximation, considering a relaxation time of 20 minutes, with a negligible charging time, a measurement every 5% of SOC, three temperatures measurements and considering the temperature changing time as negligible as well, one charge of the battery needs at least 20 hours. If the relaxation time is extended to 40 minutes, the full charge of the battery requires at least 40 hours.

Hence, this static method is non-applicable for real-life systems. Indeed, no embedded system can afford to turn off whenever it needs to update its battery's SOC, SOH or SOS. Moreover, the simple relaxation time makes the charge of a battery a day-long process. This is unrealistic for applications where the main trend is to reach 60% of the full charge within 30 minutes. Thus, the approach applicability is stopped to the laboratory measurements instead of real-time system use. Moreover, due to the need to cool down (or heat-up) the conventional entropy extraction method makes such a BMS expensive, costly and hardly applicable to the real-life systems, especially the small IoT and smartphone devices as the volume and the unit cost is too reduced for a cooling system to be an option for any company.

### (3) SOLUTIONS PROPOSED BY THE PRESENT INVENTION

Electrochemical thermodynamic measurement based dynamic entropy measurements

The proposed solution is a method to acquire an entropy profile while keeping the battery connected and working, without relying on any external cooling control method. FIG. 5 is a flowchart illustrating an algorithm of the entropy extraction method proposed by the present invention. This algorithm may be implemented as a part of the functions of BMS.

For a chargeable battery in any functional state, the BMS prevents the battery from being operated outside of a safe operation area, and manages the battery with checking necessary matters by monitoring a state of the battery, calculating secondary data, reporting the data, controlling environments of the battery, performing the battery authentication, etc.

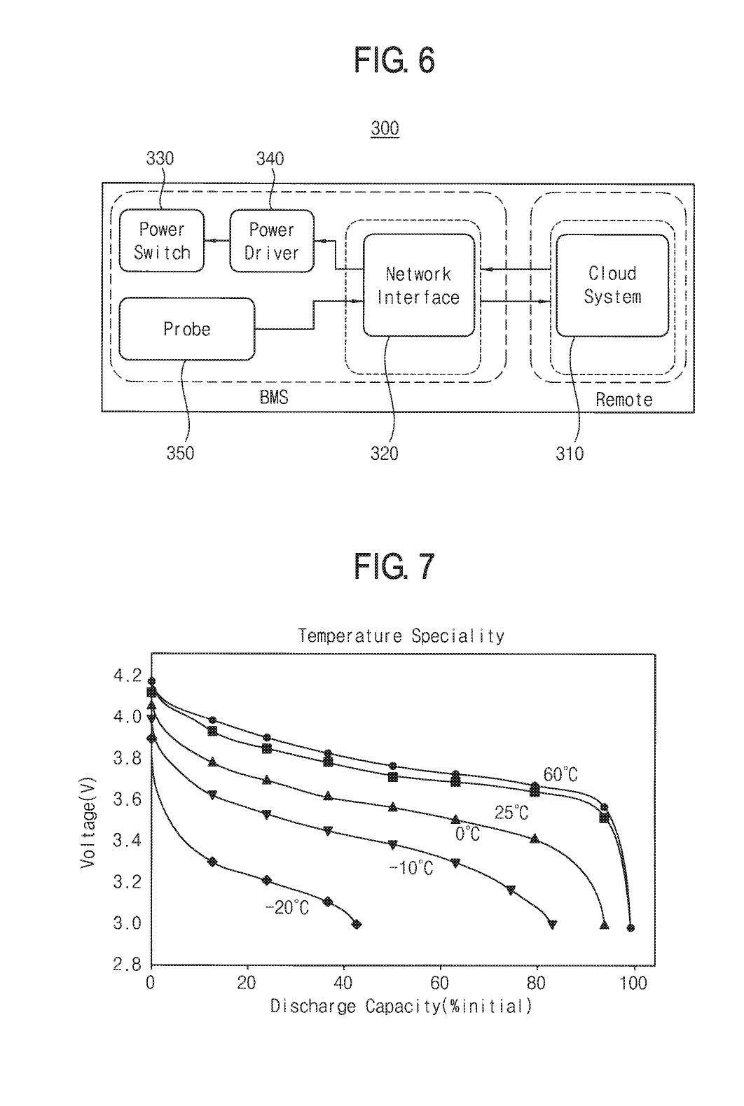

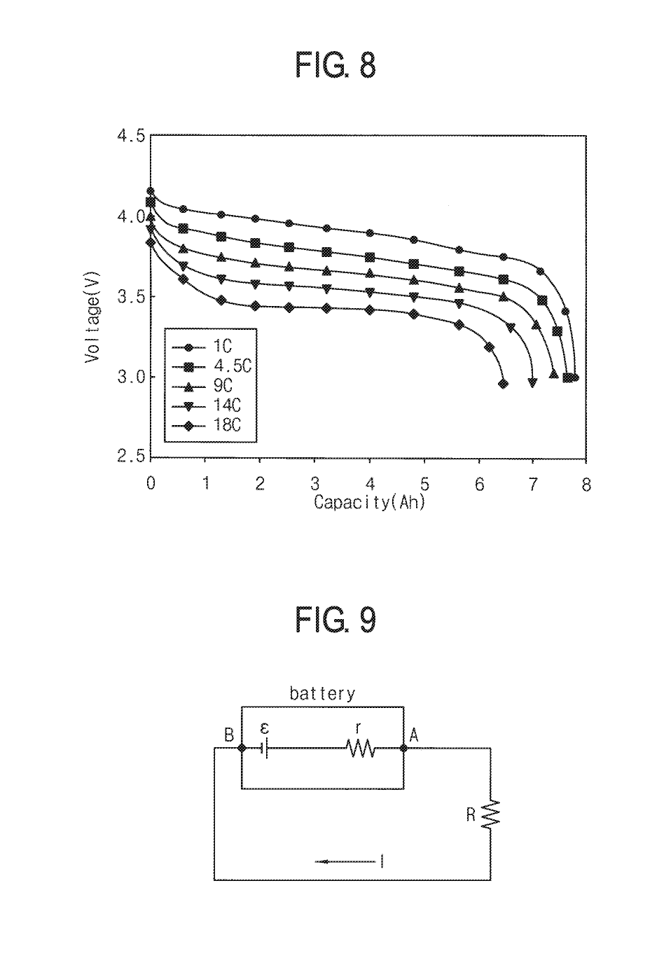

As illustrated in FIG. 6, the BMS for the application of the present invention may be a circuit board type BMS 100 that on a circuit board installed are a micro-controller (or a CPU and a memory) for performing required operations and controls by running programs and storing relevant data, a probe 120 that is connected to the battery and acquires necessary signals to be provided to the micro-controller 110, and a power IC 130 for controlling the battery-driven devices to consume less power. As illustrated in FIG. 7, the BMS for the application of the present invention may be an integrated circuit type BMS 200 implemented with a logic controller 210 and a memory 220 that have a function equivalent to that of the micro-controller 110, a power switch 230 and a power driver 240 (this drives the power switch 230 according to the control of the logic controller 210) that have a function equivalent to that of the power IC 130, and a probe 250. The BMS features of the present invention may act in conjunction with a cloud computing system. That is, the BMS apparatus for this is, as illustrated in FIG. 8, may include a network interface 320 for interfacing communications with a remote cloud system, and a power switch 330 and a power driver 340, and a probe 350 as mentioned above.

As above, the hardware configuration of the BMS applicable to the present invention may vary. Any type of BMS may carry out the functions described below in connection with the battery if it can perform required computations and controls through running relevant programs and other operations such as data storing.

The method of the present invention can be carried out while the battery is being charged or discharged. The SOC value is changed as the battery is charged or discharged. That is, during that time the state of battery may be dynamically changed. The time interval period to extract the entropy of the battery may be set based on the change in the SOC value. For example, it may be programmed that at every 5% change of the SOC relative to the SOC value of fully charged battery a loop for estimating the entropy through the measurements of temperature and OCV should be performed. Of course, the SOC estimating time interval may be set to other values depending on the needs of the system, such as, for example, 1%, 3% or 8%.

The algorithm for the BMS to extract the entropy of the battery according to the present invention is as follows.

The BMS monitors a charged level of the battery, that is, the change in the SOC while continuing to measure the SOC, in the process of charging or discharging the battery (Step S20). The SOC may be measured by an indirect way since it is difficult to measure the SOC directly.

A method for measuring the SOC is to estimate it by a linear regression method on the basis of the OCV and temperature of the battery. Since a voltage of the battery is affected by temperature, the SOC can be calculated with reference to the voltage and temperature of the battery. Specifically, the battery manufacturers provide a data sheet representing the characteristic of the battery for each battery. The battery data sheet usually contains a characteristic curve of the battery, and it is possible to determine an actual charge state (SOC) of the battery from the OCV and temperature of the battery on the basis of the characteristic curve of the battery. FIG. 9 illustrates a characteristic curve showing the relationship between the battery capacity and the OCV that is provided in a data sheet, for example, of 2200 mAh Li-Ion battery cell. The battery voltage is gradually changed in accordance with the remaining charge amount in the battery. Thus, the remaining charge amount in the battery may be estimated by a linear regression estimation using the OCV value and its corresponding temperature measurement value, and battery characteristic curve.

Another method for estimating the SOC of the battery is a method of using a Coulomb counting. The Coulomb counting method, being a fundamentally different approach than the OCV based method, is known as a current integration method. The method calculates the SOC by measuring a battery current and integrating it in time. Instead of considering the potential energy of a known-capacity battery and determining the percentage of charge remaining in it, the method considers the battery as a fuel tank. Hence by measuring the quantity of charge entering the battery during a battery charging process, the method determines the maximum capacity of the battery. Then, by counting the charge flowing out of the battery, the remaining capacity of the battery can be easily determined. The quantity of charge going in or out of the battery is determined by the integral over time interval of the current flowing in or out of the battery, hence named ‘Coulomb counting’.

As other methods, in consideration of the limitations of the two methods, that is, the OCV based SOC calculation method and the Coulomb counting based SOC calculation method, one may use another estimation method (a hybrid type method) based on these two OCV estimation methods in combination. This hybrid type method may be used in a manner that one of the two OCV estimation methods makes the other method's error to be reduced. In addition, there is also a chemical method for measuring the specific gravity and pH of the electrolyte of the battery to calculate the SOC.

The BMS monitors the change in the SOC values while measuring periodically the SOC of the battery, using any one of the methods mentioned above. And, whenever the SOC value is calculated, the BMS determines whether the measured SOC value reaches a predetermined value for the entropy extraction (Step S32). For example, if the SOC measurement period is set to 5%, at every 5% increase or decrease of the SOC value compared to that of the previous measurement period the entropy extraction loop (Steps S34-S40) that will be described below may be carried out. In other cases, it is returned back to the step S30 to continue to monitor the change in the SOC value.

In the step S32, if it is determined that the SOC value of the battery reaches the preset value for the entropy measurement, the BMS measures a battery temperature at that time right away. And at the same time, the BMS estimates the OCV of the battery (step S34). Since the OCV is the open circuit voltage of the battery, directly measuring its dynamic variation does not make sense, even hardly impossible in reality. Therefore the OCV is measured indirectly, i.e., estimated. A battery temperature may be measured, for example, in the Celsius unit, and the OCV may be measured, for example, in volts.

In step S34, several methods may be used for the OCV estimation of the battery. An exemplary method to estimate the OCV is, as mentioned in the description of the OCV estimation, a method of using the characteristic curve of the battery.

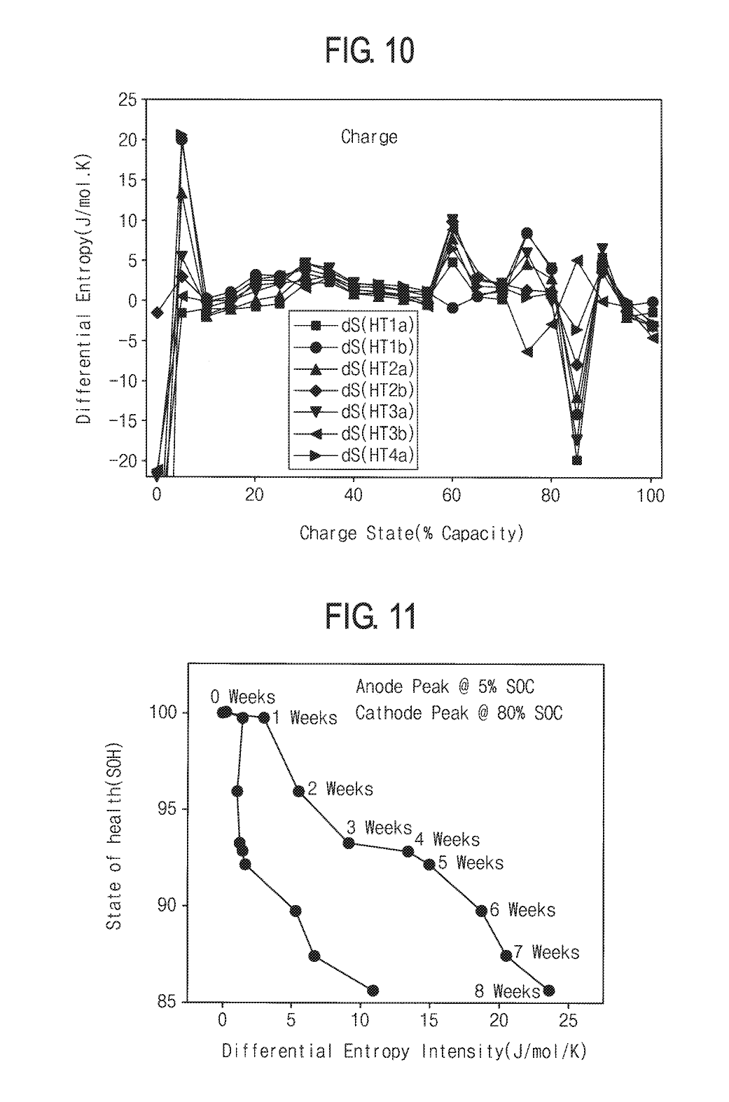

When buying a battery, a data sheet of the battery can be obtained from the battery manufacturer. The data sheet provides the technical specifications of the battery (for example, an operating range, safety working conditions, a size of the package, etc). Most battery data sheet includes information of the characteristic curve representing the relationship between the battery voltage (OCV) and the discharge capacity (SOC). The characteristic curve presents, for example, the battery voltage for different values of the discharge current as a function of the battery SOC. FIG. 10 shows an exemplary graph thereof. In order to estimate the OCV using the characteristic curve, both voltage and current are measured at the terminals of the battery. Then, selected are two curves that discharge current representing the measured current. And by using the two selected curves, values of the OCV can be estimated based on linear regression method.

Another method for estimating the OCV is to represent the battery in a simplified model, when the batteries are exposed to low frequency charge (discharge) variations and its drain (charge) current is not too high (usually 20%° or less of the rated current). For example, as shown in FIG. 11, the battery connected to a load (R) can be modeled in the form consisting of a voltage generator for generating an electromotive force (E) and an internal resistance (r). From the equation of ohm, a voltage drop occurring inside the battery can be determined as an effect of current that flows through the internal resistance.

The electromotive force (e) corresponds to the OCV, and the voltage appearing across both electrodes of the battery is the same as the electromotive force (e), that is, the OCV when no current (I) flows. In addition, when the current flows, the voltage appearing across both terminals (A, B) of the battery is equal to the sum of the electromotive force (c) and the voltage drop in the internal resistance (r). This can be represented as the following equations.

OCV=ε (4-1)

V_batt_{I=0}=OCV (4-2)

V_batt_{I≠0}=ε+r·I (4-3)

If so, it is possible to estimate the OCV using the above equations according to its reverse process, by measuring the voltage and current of the battery when a current flows through the load, in the state that the internal resistance value is known.

The OCV estimation is also possible by Kalman filtering as another method. The Kalman filtering is an algebraic iterative method used in many domains when one has to estimate precisely the value of a state variable but can only measure its effects or derivate signals. The method is fairly simple in concept but can be challenging to apply as an algorithm. Its concept is as follow: (i) A system for it is filled with the previous estimated state of the variables; (ii) From measurement, the previous estimated state and a custom model of the system, the next state is estimated, then from the state an estimation is made over a measurable parameter value; (iii) The parameter is then measured, and the estimation error (measure .vs. estimation) is computed; (iv) From the estimation error the estimated state is corrected and used to feed an input of the system for the next step. This method follows a step by step process. Its precision depends on the model on which it relies and on the estimation temporal step compared to the variation speed of the system under surveillance.

By running an OCV estimation module that is implemented as a program based any one out of the methods mentioned above, an OCV at the current state can be estimated. In addition to the OCV, it is also required of the battery temperature in order to calculate the battery entropy. Therefore, the battery temperature may be also measured along with the OCV estimation (Step S34). The battery temperature can be directly measured in real time by using a temperature sensor. In some cases, the temperature may be indirectly measured, or an approximated value of the temperature may be used based on the room temperature or weather information where the battery exists.

It is needed to measure the entropy over the full range of the SOC in order to determine the SOH and SOS. Therefore, this point should be considered in determining the resolution of SOC setting value in step S32 that is used as a reference point for measuring the temperature and the OCV of the battery. The battery temperature and OCV measurements may be carried out over several cycles at a specific SOC value. The number of the measurements may be determined in consideration of the precision expected and the entropy usual evolution rate of a normal system. For example, it may vary between 2 and the number as much as the user wants.

Over two consecutive charge/discharge cycle, the temperature has a very little change to stay the same. So, OCVs at same SOC but different temperatures are measured from cycle to cycle. Assuming that the entropy evolution is not significant and then relying on the relationship described by equation (1), its value may be determined over some cycles (for error correction).

The temperature value measured and the OCV value estimated in step S34 is stored in a database of the storage means within the BMS (step S36).

Then, on the basis of these measured values, operations for calculating the entropy of the battery may be conducted (step S38). The entropy calculation may be done by using the following equation.

$$k \frac{Δ {OCV}_{estimated}}{Δ {T}_{measured}} = Δ {S}_{new} ( SoC @ value ) \qquad ( 5 )$$

In other words, a variation of entropy newly measured at a specific SOC value (ΔS_{new}: the difference between the entropy estimated in the previous cycle and the entropy estimated at the current period) is proportion to a value obtained by dividing a variation of the estimated OCV value (ΔOCV_{estimated}: a difference between the estimated OCV value of the previous cycle and the estimated OCV value of the current cycle) by a variation of the measured temperature value (ΔT_{measured}: a difference between the measured temperature value of the previous cycle and the measured temperature value of the current cycle). Here, k is a constant proportional constant.

The grounds that the above entropy calculation expression is obtained are as follows. Gibb's energy represents the amount of ‘useable’ energy in a chemical system. In the case of a battery, this energy can be translated into electricity. Hence the Gibb's energy is the quantification in Joules of the charge present in a battery at defined instant times the voltage of the battery at that very moment. The Gibb's energy is, in the case of a battery, determined by the following equation.

ΔG(x)=−nFE₀(x) (6)

It is defined by the state of the battery at the moment of observation. And in a battery system, because the initial energy E₀(x) is the OCV, the equation (6) can be rewritten as follows.

ΔG(x)=−nF·OCV (7)

Here, x represents the percentage of the chemical reaction done, hence the amount of charge remaining, n being the amount of electron exchange in the typical elementary reaction, and F being the Faraday constant.

Further, according to the second law of thermodynamics, the Gibb's energy can be expressed as the following equation:

ΔG(x)=ΔH−TΔS (8)

Here, enthalpy H is the algebraic representation of the total amount of energy in the system, that is, sum of the useable one and the unusable one (potential energy, kinetic energy if any). In the case of a battery, as no external force is existent, the system can be reduced to a thermos-chemical analysis.

From the above equations (7) and (8),

k·OCV=−ΔH+TΔS (9)

And, differentiating this equation with respect to temperature T gives the following equations.

$$k ( OCV ) = - \frac{δ Δ H}{δ T} + T \cdot S + \frac{δ Δ S}{δ T} \qquad ( 10 )$$

In the general case, we can consider the battery system as a kind of quasi-static system and hence through the approximation of Ellingham we can assume that at a fixed value of x, neither entropy (ΔS) nor enthalpy (ΔH) is a function of the temperature. Therefore, the first and third terms of the right-hand side in the above equation (10) become zero (0), and thus the equation (10) can be simplified as follows.

K(OCV)=T·S (11)

Thus it can be seen that the entropy variation ΔS can be extracted from the differential value of the OCV over the battery temperature T as shown in equation (5). Like this, if extraction of entropy variations is done at every measurement cycle, the full entropy profile until the battery is fully charged can be obtained.

Once the variation of entropy ΔS has been calculated in the step S38, it may be utilized in many ways. For example, the entropy value may be updated to estimate the SOH and SOS, and the SOH and SOS can be determined based on the variation of the entropy ΔS (step S40). Therefore, the battery's state functions SOH and SOS can be computed from the measurement around specific points through the calculus of differential entropy, with no need for any continuous monitoring.

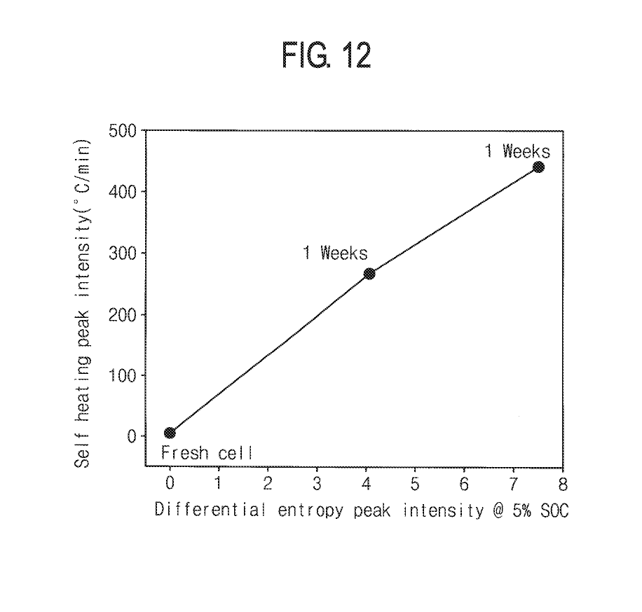

The entropy of the battery does not evolve over battery's aging homogeneously over the entire range of the SOC. In fact, there are two values of the SOC that show a very strong variation on entropy in the aging of the battery. They are an area equal to or less than 15% and another area equal to or larger than 85% (Refer to the graph in FIG. 12 illustrating the variation on the entropy as a function of SOC).

The variation on the entropy in these values is substantially proportional to the battery capacity (refer to the graph shown in FIG. 13) and the self-heating rate (refer to the graph shown in FIG. 14). Thus, because SOH is an estimation of the battery capacity loss due to aging, the differential entropy would be a perfect tool to estimate the SOH through a reference equation (which can be obtained in laboratory prior to the implementation of the BMS). The self-heating rate is a chemical state function that determines the thermal runaway capability of the battery. Here it means the probability that the battery will take fire spontaneously within the safety operation limits. Hence it provides the SOS.

In order to determine accurately the point where to calculate the entropy, it is important to recognize that the SOC value must be exactly determined.

To determine the entropy, there is no need for the battery to be unplugged and to have a controllable temperature. Therefore, the present invention, without preventing the battery from doing any task, provides a method to extract entropy estimation from the battery that is servicing any work. In the recent years, rechargeable secondary batteries have received spotlight and among them the lithium-based battery is most commonly used. The present invention can be applied to the BMS employed by all the devices using the lithium-based battery. The present invention may be applied in a form of block to the BMS. The block added may be implemented in software and/or hardware. The BMS may be designed such that it can be associated with the battery in the system at a remote location via an interface to exert the functions of the present invention.

The present invention is applicable to a BMS for a variety of secondary batteries, including a lithium-based battery. It is also applicable to the wearable devices, electric vehicles, and portable devices.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present disclosure. Accordingly, all such modifications are intended to be included within the scope of the present disclosure as defined in the claims.

What is claimed is:

1. A method of dynamically estimating entropy of a battery using a program run in a battery management system (BMS) connected with the battery, comprising:
measuring a temperature of the battery of which functional state is varying;
estimating an open circuit voltage (OCV) of the battery around a time of measuring the temperature; and
estimating variation of entropy of the battery based on the temperature measured and the OCV estimated.

2. The method of claim 1, further comprising estimating a state of charge (SOC) of the battery while continuously monitoring the SOC and comparing an SOC value estimated with a measurement reference value preset to determine whether the SOC value estimated is equal to the measurement reference value, wherein when the SOC value estimated is equal to the measurement reference value, the estimating the OCV and the estimating variation of entropy are carried out.

3. The method of claim 2, wherein the SOC value estimated is calculated by a linear regression analysis method to estimate a remaining charge amount based on a predetermined battery temperature and the OCV of the battery.

4. The method of claim 2, wherein the SOC value estimated is calculated by a Coulomb counting method to measure a battery current and integrate the battery current with time.

5. The method of claim 2, wherein the SOC value estimated is calculated by Kalman filtering.

6. The method of claim 2, wherein the measurement reference value can be set variably.

7. The method of claim 1, further comprising calculating a state of health (SOH) and/or a state of safety (SOS) indicating a risk of the battery based on the variation of entropy of the battery.

8. The method of claim 1, wherein the variation of entropy is estimated based on correlation between the OCV and the battery temperature, obtained by measuring the SOC, the battery temperature, and the OCV over two or more cycles.

9. The method of claim 1, wherein the estimating of the variation of entropy is carried out over a full range of the SOC.

10. The method of claim 1, wherein the estimating of the variation of entropy is carried out whenever a value of the SOC is changed by the measurement reference value.

11. The method of claim 1, wherein the OCV is obtained not by a direct measurement but by estimation based on the SOC value estimated and the battery temperature.

12. The method of claim 1, further comprising storing the temperature measured and the OCV estimated in a database of the BMS.

13. The method of claim 1, wherein the method is implemented into an integrated circuit system or as a logic circuit.

14. The method of claim 1, wherein the method is implemented as a program run on a general purpose CPU or MCU.

15. The method of claim 1, wherein the method is implemented as a program run on a cloud computing system.
